(19) United States
(12) Patent Application Publication
(10) Pub. No.: US 2007/0178708 A1
(43) Pub. Date: Aug. 2, 2007

(54) VAPOR DEPOSITION SYSTEM AND VAPOR DEPOSITION METHOD FOR AN ORGANIC COMPOUND

(75) Inventor: Nobutaka Ukigaya, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/627,752

(22) Filed: Jan. 26, 2007

(30) Foreign Application Priority Data
Jan. 27, 2006 (JP) 2006/018519
Jan. 10, 2007 (JP) 2007/001935

(51) Int. Cl. H01L 21/31

(52) U.S. Cl. 438/758

(57) ABSTRACT

There is provided a vapor deposition system including a vapor depositing source, holding means for holding a substrate, moving means, and an opening member having an opening, the moving means moving at least one of the substrate, and, the vapor depositing source and the opening member, in one direction in a plane in parallel with a plane including the substrate, and the opening member being disposed between the vapor depositing source and the substrate and having an opening having a width at a center of the opening in a direction of movement which is smaller than that at ends the opening. In the system, the plurality of vapor depositing sources are arranged along a direction in a plane, which is a direction intersecting the direction of movement, and the opening member has a plurality of openings each independently disposed so as to correspond to each of the plurality of vapor depositing sources.

### BACKGROUND OF THE INVENTION

1. Field of the Invention

The present invention relates to a vapor deposition system and a vapor deposition method for an organic compound for forming an organic compound layer of an organic light emitting device or the like.

2. Description of the Related Art

FIGS. 13A to 13D illustrate a typical method of manufacturing an organic light emitting device (organic EL) First, a conductive film of high reflectivity is formed on a substrate 101 such as a glass substrate. By patterning the conductive film in a predetermined shape, an anode electrode 102 is formed. Then, a device separating film 103 formed of a highly insulating material is formed so as to surround a pixel 101a on the anode electrode 102. With this, adjacent pixels 101a are partitioned by the device separating film 103. Next, a hole transporting layer 104, an organic light emitting layer 105, an electron transporting layer 106, and an electron injecting layer 107 are formed in sequence by vapor deposition on a surface of the substrate including the anode electrode 102. By laminating a cathode electrode 108 formed of a transparent conductive film on the electron injecting layer 107, a plurality of organic light emitting devices are formed on the substrate 101.

Finally, the plurality of organic light emitting devices on the substrate are covered with an encapsulating layer which is not shown and which is formed of a material having low moisture permeability. It is to be noted that, in vapor deposition of each organic compound layer, a mask having an opening provided therein so as to correspond to the region in the surface of the substrate where the vapor deposition is to be carried out is used. Further, in the case of a full color organic EL display device, it is necessary to form on the substrate three kinds of devices that emit red light, green light, and blue light, respectively. Therefore, a corresponding mask 110 having a plurality of openings corresponding to predetermined pixels, respectively, is used to apply one kind of corresponding deposition material among three kinds of vapor deposition materials to one kind of the corresponding devices among the three kinds of devices.

In an organic light emitting device, which displays an image by active matrix driving, it is necessary to provide in advance a thin film transistor (TFT) on the substrate and to electrically connect a drain electrode of the TFT with a cathode electrode of the organic light emitting device.

Next, a vapor deposition process for vapor deposition of the organic compound layer, which is especially the organic light emitting layer, of the above-mentioned organic EL is described.

In a typical organic EL manufacturing apparatus, a substrate is disposed in a vacuum chamber, and a vapor depositing source is disposed below the substrate. A vapor deposition material evaporates isotropically from substantially the center of an opening corresponding to an evaporation opening of the vapor depositing source with an axis along the direction of the normal to the surface including the opening being as the central axis, and the evaporated material flies in the vacuum to adhere to the surface of the substrate. When the vapor depositing source comes nearer to the substrate, the amount of adhesion of the evaporated material to the substrate per unit time, that is, the vapor deposition rate increases. However, when the vapor depositing source comes nearer to the substrate, the difference between the distance from the vapor depositing source to the center of the substrate and the distance from the vapor depositing source to an end of the substrate becomes larger, and thus, the film thickness distribution of the deposited film adhered to the surface of the substrate becomes wider. Because, on the other hand, the light emitting characteristics of an organic EL device depends on the thickness of the organic compound layer forming the device, it is not allowable that a wide film thickness distribution is formed on the surface of the substrate. Therefore, in the above conventional manufacturing apparatus, the organic light emitting device has to be manufactured with an enough distance between the substrate and the vapor depositing source. As a result, material use efficiency which is the ratio of material adhered to the substrate to the whole evaporated material is very low, and the vapor deposition rate is decreased, accordingly. Therefore, the manufacturing cost is high and the throughput in mass production is low. Further, as the manufacturing apparatus becomes larger, the cost of equipment increases.

On the other hand, according to a method disclosed in Japanese Patent Application Laid-Open No. 2001-93667, by disposing a film thickness correcting plate (opening member) having an opening provided therein between a vapor depositing source and a substrate, the vapor deposition rate can be enhanced without loss of uniform film thickness. Japanese Patent Application Laid-Open No. 2001-93667 discloses that, by forming an opening in the film thickness correcting plate such that, among material which flies from the vapor depositing source, only material substantially vertically incident on the substrate passes therethrough, a vapor deposition film with a uniform film thickness distribution is obtained. Further, according to a method disclosed in Japanese Patent Application Laid-Open No. 2004-107764, by providing an aperture with the width at its center larger than that at its ends, the film thickness at the center of the aperture is also prevented from becoming thick, and the film thickness distribution can be made uniform along the length of the aperture. Further, Japanese Patent No. 2798194 discloses a fluorescent substance vapor deposition system including a regulating member having a slit shaped similarly to the one disclosed in Japanese Patent Application Laid-Open No. 2004-107764.

However, even according to the method disclosed in Japanese Patent Application Laid-Open No. 2001-93667, there is a problem in that the material use efficiency is sacrificed. The reason is that, because velocity vectors in the space of the material evaporated from the vapor depositing source are not necessary ones perpendicular to the substrate, to decrease the ratio of the vapor deposition material adhered to other than the substrate is difficult.

Further, although Japanese Patent Application Laid-Open No. 2004-107764 discloses a structure in which a member having an opening provided therein is provided between a vapor depositing source and a substrate, nothing discloses a relationship between, when there are a plurality of vapor depositing sources, the vapor depositing sources and a member having an opening provided therein. When there are a plurality of vapor depositing sources, it is necessary to change the arrangement of the openings, the shape of the openings, and the like, taking into consideration the interaction between the plurality of vapor depositing sources and the like.

The present invention has been made in view of the above problems of related art, and an object of the present invention is to provide a vapor deposition method and a vapor deposition system of an organic compound, which can materialize uniform film thickness, a high vapor deposition rate and high material use efficiency in manufacturing an organic light emitting device.

### SUMMARY OF THE INVENTION

A vapor deposition system according to the present invention comprises a plurality of vapor depositing sources; a holding member for holding a substrate on which a film is to be formed; and opening member disposed between the vapor depositing source and the substrate on which a film is to be formed, the opening member having openings each independently disposed so as to correspond to the plurality of vapor depositing sources; and moving means for moving at least one of the substrate on which a film is to be formed, and, the vapor depositing sources and the opening member, in one direction in a plane in parallel with a plane including the held substrate on which a film is to be formed, wherein the plurality of vapor depositing sources are arranged along a direction in the plane, which is the direction intersecting the direction of the movement, and a width at a center of the opening in the direction of movement is smaller than that at ends of the opening.

Further, according to another aspect of the present invention, a vapor deposition system comprises a plurality of vapor depositing sources; a holding member for holding a substrate on which a film is to be formed; a plurality of opening members each disposed between the vapor depositing sources and the substrate on which a film is to be formed, the plurality of opening members being independently disposed so as to correspond to the plurality of vapor depositing sources; moving means for moving at least one of the substrate on which a film is to be formed, and, the vapor depositing sources and the opening members, in one direction in a plane in parallel with a plane including the held substrate on which a flm is to be formed; and a partitioning member disposed between the plurality of vapor depositing sources, wherein the plurality of vapor depositing sources are arranged along a direction in the plane, which is a direction intersecting the direction of the movement, and a width at a center of each of the openings in the direction of movement of the openings is smaller than that at ends of the each of the openings.

By changing the shape of the openings in the opening member, fluctuation of the vapor deposition rate is compensated, and the film thickness distribution of the film deposited on the substrate is made uniform. This makes it possible to manufacture an organic light emitting device with high material use efficiency.

Further features of the present invention will become apparent from the following description of exemplary embodiments with reference to the attached drawings.

### BRIEF DESCRIPTION OF THE DRAWINGS

FIG. 1 is a schematic sectional view illustrating a vapor deposition system according to Example 1 of the present invention.

FIG. 2 is a schematic perspective view for explaining the arrangement of a film thickness correcting plate of the system of FIG. 1.

FIG. 3 is a plan view illustrating a shape of an opening in the film thickness correcting plate.

FIG. 4 is a graph of a relationship between vapor deposition time period versus film thickness of an organic compound.

FIG. 5 is a schematic perspective view of an embodiment having a partitioning member.

FIG. 6 is a schematic perspective view of another embodiment having a partitioning member.

FIG. 7 is a schematic sectional view of still another embodiment having partitioning members.

FIG. 8 is a plan view illustrating a shape of openings in the film thickness correcting plate.

FIG. 9 is a schematic sectional view of another embodiment having partitioning members.

FIG. 10 is a schematic perspective view illustrating a vapor deposition system according to a reference example.

FIG. 11 is a schematic sectional view illustrating a vapor deposition method according to Example 2.

FIG. 12 is a schematic sectional view for explaining a vapor deposition method according to Example 3.

FIGS. 13A, 13B, 13C, 13D and 13E illustrate a typical method of manufacturing an organic light emitting device.

### DESCRIPTION OF THE EMBODIMENTS

A vapor deposition system according to the present invention has a vapor depositing source, holding means, moving means, and an opening member having an opening provided therein.

The holding means is holding means for holding a substrate on which a film is to be formed. The moving means is moving means for moving at least one of the substrate on which a film is to be formed, and, the vapor depositing source and the opening member, in one direction in a plane in parallel with a plane including the held substrate on which a film is to be formed. The opening member is disposed between the vapor depositing source and the substrate on which a film is to be formed, and has an opening with the width at the center thereof is smaller than that at ends thereof in the direction of the movement.

Further, the vapor deposition system according to the present invention has a plurality of vapor depositing sources arranged in the plane in parallel with the plane including the held substrate on which a film is to be formed in a direction intersecting the direction of the movement, and the opening member has openings provided therein so as to be independent of each other and so as to correspond to the plurality of vapor depositing sources, respectively.

When there are a plurality of vapor depositing sources in the direction intersecting the direction of the movement, it is possible to have an opening member having one opening corresponding to the plurality of vapor depositing sources, but the area of the opening becomes larger. As a result, the opening member is more liable to undergo deflection and distortion, and thus, it is difficult to sufficiently attain a uniform film thickness distribution, which is an object of the present invention. Such deflection and distortion become remarkable under the influence of heat from the vapor depositing sources or the like. According to the present invention, the opening member has openings provided therein so as to be independent of each other and so as to correspond to the plurality of vapor depositing sources, respectively. Therefore, the area of the openings are not too large, deflection and distortion are less liable to occur, and thus, a uniform film thickness distribution can be attained.

In the following, the best mode for carrying out the invention is described with reference to the attached drawings.

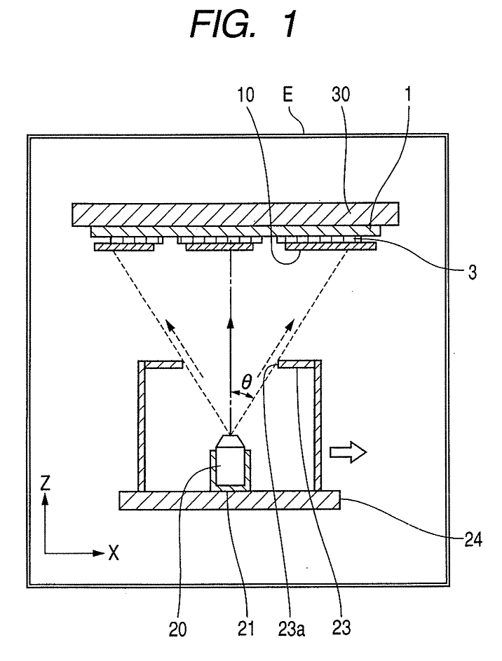

FIG. 1 is a schematic sectional view illustrating a manufacturing apparatus of an organic light emitting device according to an embodiment of the present invention. The apparatus is used for, for example, manufacturing an organic electroluminescent device (organic light emitting device). In a vacuum chamber E, a mask 10 is brought into contact with a device separating film 3 on a substrate 1, and an organic compound evaporated from a vapor depositing source 20 is made to be deposited on the substrate 1 via the mask 10. A film thickness correcting plate 23 which is an opening member having an opening 23a provided therein is provided between the vapor depositing source 20 and the substrate 1. The film thickness correcting plate 23 is, together with the vapor depositing source 20 and a heater 21, moved by a moving stage 24 as moving means in an X direction (first direction) as illustrated by an arrow. The organic compound evaporated from the vapor depositing source 20 flies and spreads in the vacuum, and then, the organic compound in a range of angle θ passes through the opening 23a in the film thickness correcting plate 23 as illustrated by arrows to adhere to the substrate 1. The angle θ corresponds to the incident angle of the organic compound on the substrate 1.

The vapor depositing source 20 is a point source, and the point source is provided with the heater 21 for heating the evaporated material. A point source refers to a container which contains an evaporated material and the temperature of which can be adjusted. It is a vapor depositing source, and an opening having an area small enough compared with the area of the substrate is provided in a part thereof, and evaporated molecules are ejected from the opening to carry out vapor deposition. In a structure in which a plurality of vapor depositing sources which are point sources are arranged, compared with a structure disclosed in Japanese Patent Application Laid-Open No. 2004-107764 in which an evaporation source which is rectangular in shape so as to correspond to the substrate is disposed, because the influence of heat on the substrate is smaller, the vapor depositing sources can be disposed nearer to the substrate. As a result, the amount of the vapor deposition material adhered to other than the substrate can be decreased, and thus, the process yield can be improved and the maintenance cycle of the vapor deposition system can be made longer.

The vapor depositing source 20 and the film thickness correcting plate 23 are moved in the X direction as illustrated by the arrow or in the opposite direction with respect to the substrate 1, with their relative position maintained. The mask 10 for vapor depositing the organic compound only on a predetermined place on the substrate 1 is disposed on the side of the vapor depositing source with respect to the substrate so as to be in contact with or in proximity to the substrate 1. In FIG. 1, the mask 10 is disposed so as to be substantially in contact with an upper surface of the device separating film 3 provided on the substrate 1. By disposing a substrate holding mechanism 30 as holding means on a rear surface of the substrate 1, the substrate 1 and the mask 10 are held. The internal pressure of the vacuum chamber E is made to be about 1×10⁻⁴-1×10⁻⁵ Pa by an exhaust system.

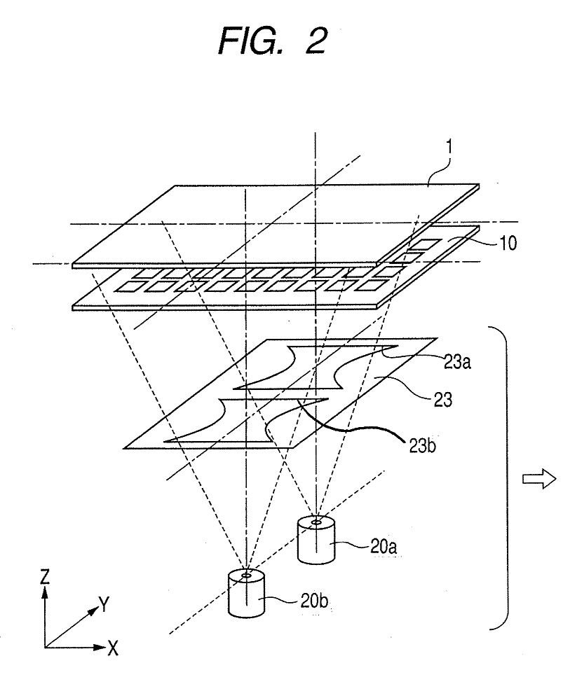

FIG. 2 is a perspective view illustrating the positional relationship among the vapor depositing sources 20a and 20b, the film thickness correcting plate 23, the mask 10, and the substrate 1 of the manufacturing apparatus according to the embodiment of the present invention. FIG. 2 schematically illustrates a case in which two vapor depositing sources 20a and 20b are used. When a plurality of vapor depositing sources 20a and 20b are arranged in a Y direction in this way, the film thickness correcting plate 23 as the opening member has openings 23a and 23b which are independent of each other and which correspond to the plurality of vapor depositing sources 20a and 20b, respectively. The center of the corresponding vapor depositing source 20a or 20b is aligned with the center of the corresponding opening 23a or 23b in the film thickness correcting plate 23 in which the width of the opening in the X direction is the smallest. Alternatively, when, instead of single film thickness correcting plate 23, a plurality of film thickness correcting plates are disposed between the vapor depositing sources and the substrate on which a film is to be formed, the plurality of film thickness correcting plates may be independently disposed so as to correspond to the plurality of vapor depositing sources.

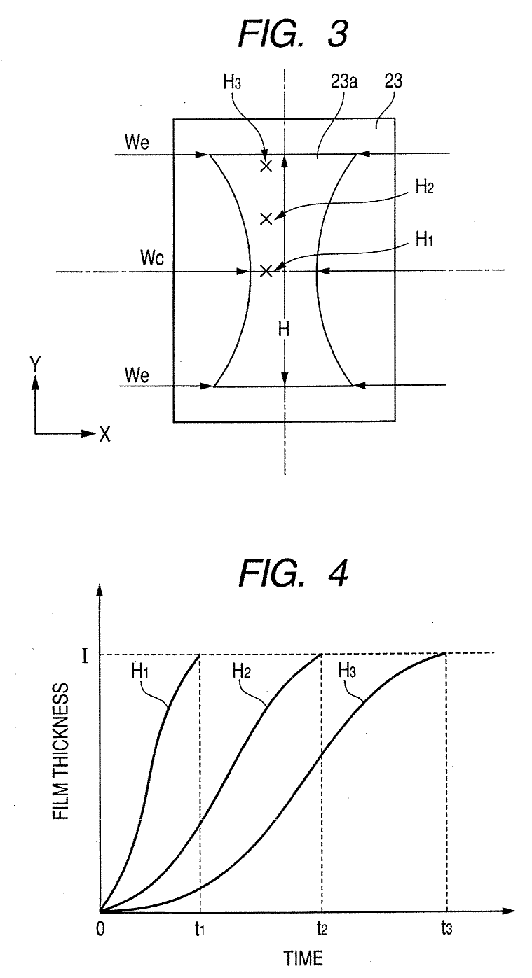

As illustrated in FIG. 3, the opening 23a in the film thickness correcting plate 23 is a patterned opening in the shape of an hourglass, and the width Wc of the opening at the center is smaller than the width We of the opening at ends. The opening is symmetrical with respect to a line in the Y direction (second direction). It is to be noted that, in the drawings referred to in the following, like reference numerals designate like or identical members or places.

Next, the shape of the opening in the film thickness correcting plate 23 is described in detail.

A case where the vapor depositing source 20 is a point source and evaporates one organic compound is described. Because the organic compound evaporated from the point source spreads according to the cosine law, the film thickness distribution on the substrate is formed so as to be concentric. Therefore, there is a tendency that the film thickness becomes smaller from the center toward ends of the substrate 1. It follows that, when the center of the vapor depositing source 20 is aligned with the center of the substrate surface, the vapor deposition rate becomes lower along the direction from the center of the substrate toward ends of the substrate.

It is to be noted that, in the present invention, the shape of distribution of the evaporate rate of the organic compound evaporated from the vapor depositing source 20 does not have to be strictly concentric with respect to the center of the vapor depositing source 20, and may be in a shape with which the material use efficiency is not substantially greatly impaired. If that is satisfied, the concentric distribution of the evaporate rate described here includes one in which some of the circles are not perfect ones and one in which centers of some of the circles are offset from the center of other concentric circles.

When vapor deposition continues with the substrate 1 moved in the X direction with respect to the vapor depositing source 20, film thickness 1 at coordinates (X1, Y1) on the substrate is determined by taking the integral of vapor deposition rate V with respect to vapor deposition time period t as expressed by the following equation (1):

l=∫V dt. (1)

When the vapor depositing source 20 the vapor deposition rate of which is constant is moved with respect to the substrate 1 at constant relative velocity, the film thickness in the X direction is substantially uniform. On the other hand, because the film thickness distribution in the Y direction is in accordance with the cosine law described in the above, time correction is necessary.

Therefore, as illustrated in FIG. 3, the width in the X direction of the opening 23a in the film thickness correcting plate 23 is gradually made larger farther away from the center of the opening, and the pattern is in a shape such that the vapor deposition time period becomes longer at the ends of the opening in which the vapor deposition rate is relatively slow.

More specifically, the width of the opening in the film thickness correcting plate 23 is determined such that the relationship expressed by the following equation (2) is satisfied:

tc=Wc/s

te=We/s, and

∫Vc dt [0, tc]=∫Ve dt[0, te] (2)

where s is the velocity of movement of the vapor depositing source 20, Vc is the vapor deposition rate at the center of the opening, tc is the vapor deposition time period at the center of the opening, Wc is the width of the opening in the X direction at the center of the opening, Ve is the vapor deposition rate at the ends of the opening, te is the vapor deposition time period at the ends of the opening, and We is the width of the opening in the X direction at the ends of the opening.

FIG. 4 is a graph illustrating change over time in the film thickness in vapor deposition at points H₁, H₂, and H₃ within the opening 23a in the film thickness correcting plate 23 of FIG. 3. Because the relationship among the average vapor deposition rates at the respective points is H₃<H₂<H₁, the relationship among the vapor deposition time periods necessary for attaining the predetermined film thickness at the respective points is H₁<H₂<H₃.

Therefore, by making smallest the incident angle on the substrate 1 of the vapor deposition material passing through the opening 23a in the film thickness correcting plate 23 at a place corresponding to the center of distribution of evaporation of the vapor depositing source 20 and by making largest the incident angle at the ends of the opening in the film thickness correcting plate 23, even components which are obliquely incident are vapor deposited on the substrate 1 to make uniform the film thickness distribution.

By using the film thickness correcting plate with the opening shaped in this way, a film the film thickness distribution of which is uniform can be formed even when the vapor depositing source is disposed near to the substrate, and thus, high material use efficiency can be obtained.

Because it is not necessary to decrease the vapor deposition rate even if the substrate becomes larger, high throughput is possible. Further, because, compared with the related art, one vapor depositing source can carry out vapor deposition on a larger surface, increase in the number of vapor depositing sources as the substrate becomes larger can be suppressed.

When the distribution of the vapor deposition rate of the material evaporated from the vapor depositing source is in the shape of concentric circles or concentric ovals with the center thereof being a place corresponding to the center of the vapor depositing source, the shape of the opening in the film thickness correcting plate for enhancing the material use efficiency can be uniquely designed.

It is to be noted that the present embodiment by no means limits the structure of the vapor depositing source, the number of the vapor depositing source(s), the kind of the organic compound, the shape of the opening in the mask, and the like. For example, a Knudsen cell, a valve cell, or the like may be used as the vapor depositing source. Further, the vapor depositing source may be a commonly used vapor depositing source for vapor depositing a plurality of organic compounds at the same time.

Further, although the above embodiment describes a structure in which the moving means moves the vapor depositing source and the opening member, the present invention is not limited thereto. The structure may be one in which the moving means moves the substrate held by the holding means, and may be one in which the moving means moves all of the vapor depositing source and the opening member and the substrate. In other words, the structure may be any one in which the relative position of the vapor depositing source and the substrate is changed.

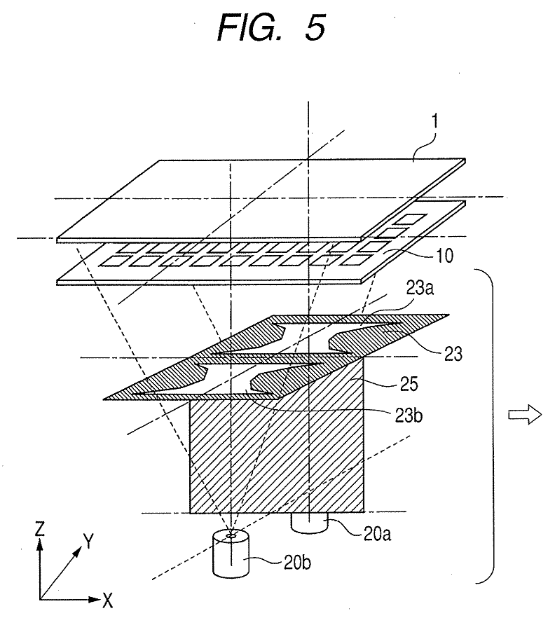

FIG. 5 is a schematic view of a structure in which a partitioning member 25 is provided between two vapor depositing sources 20a and 20b of the vapor deposition system illustrated in FIG. 2. By providing the partitioning member 25, the vapor deposition material from the plurality of vapor depositing sources can be prevented from passing through an opening other than the corresponding opening, which is preferable. More specifically, the vapor deposition material ejected from the vapor depositing source 20a is prevented from passing through an opening 23b to form a film on the substrate 1, while the vapor deposition material ejected from the vapor depositing source 20b is prevented from passing through the opening 23a to form a film on the substrate 1. Because the vapor deposition material which passes through an opening other than the corresponding opening to form a film on the substrate 1 has a large incident angle with respect to the substrate, the mask 10 or the like becomes an obstacle and the amount of the vapor deposition material forming the film differs between a peripheral portion and the center of the openings in the mask, which makes the film thickness ununiform. Such a problem can be solved by providing the partitioning member 25. It is to be noted that, when the vapor deposition material which passes through an opening other than the corresponding opening goes outside the substrate 1 as illustrated in FIG. 2, no film is thereby formed on the substrate 1, and thus, the partitioning member is not necessarily required.

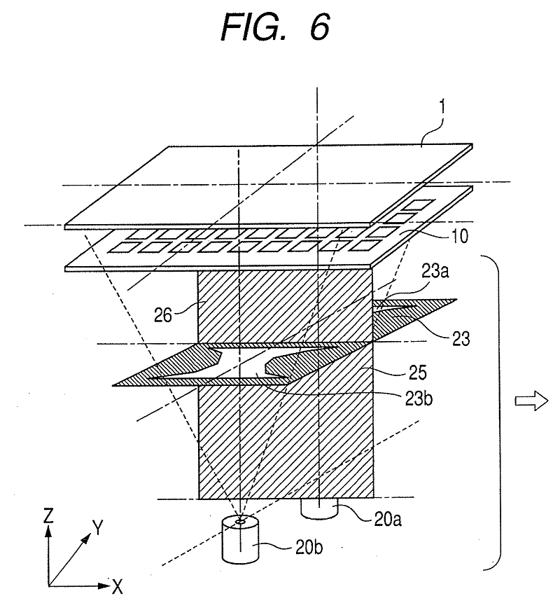

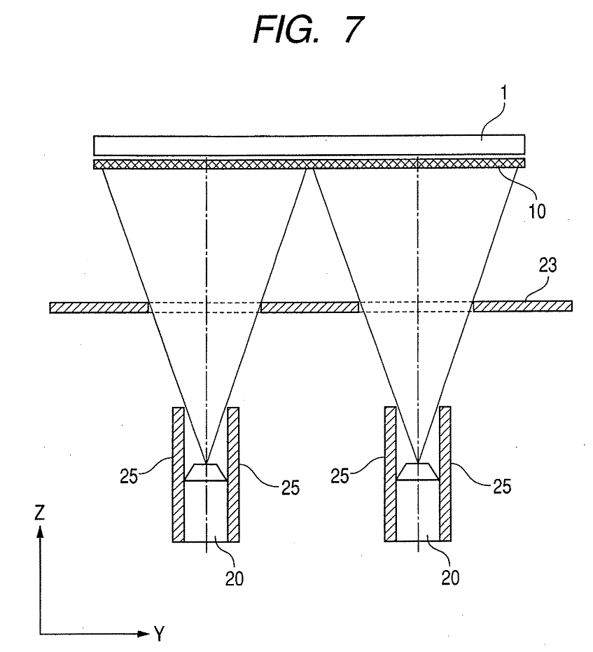

FIG. 6 is a schematic view of a structure in which the partitioning member 25 is disposed both on the side of the vapor depositing source 20 of the opening member 23 and on the side of the substrate 1 of the opening member 23. By providing the partitioning member 25 not only on the side of the vapor depositing source 20 of the opening member 23 but also on the side of the substrate 1 of the opening member 23, the vapor deposition material which passes through openings different from each other, respectively, can be prevented from being mixed with each other. More specifically, the vapor deposition material which passes through the opening 23a and the vapor deposition material which passes through the opening 23b can be prevented from being mixed with each other. Further, the partitioning member 25 may be members disposed adjacent to side portions of the vapor depositing sources 20 as illustrated in FIG. 7.

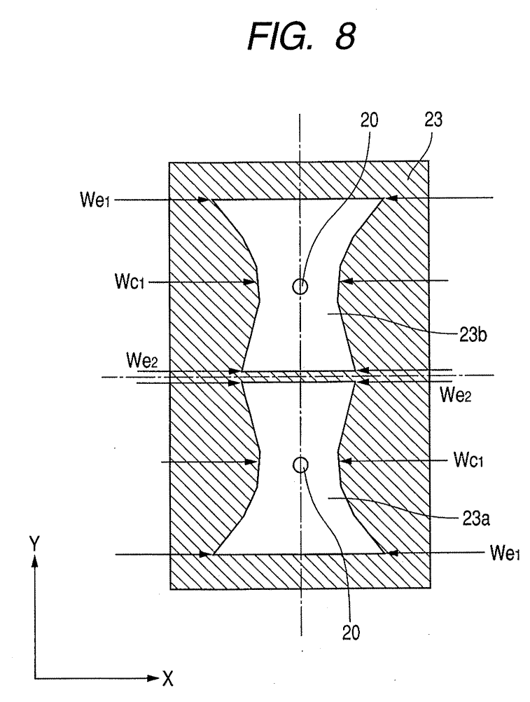

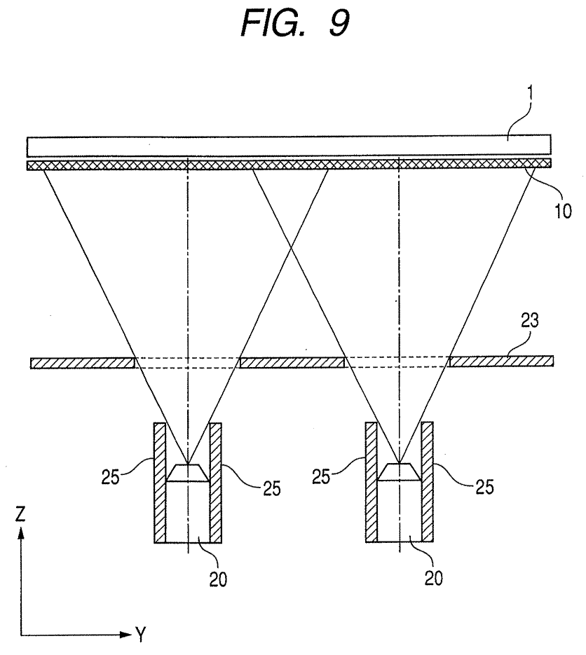

When the vapor deposition material which passes through openings different from each other, respectively, is mixed with each other, it is necessary to make the shapes of the openings 23a and 23b asymmetrical with respect to a line in the X direction differently from the ones illustrated in FIG. 3. More specifically, the width of the opening in the direction of the movement at the end nearer to the adjacent opening is smaller than that at the end nearer to an end of the opening member 23. More specifically, as illustrated in FIG. 8, the width Wₑ₂ at the corresponding end of opening 23a or 23b disposed nearer to the adjacent opening 23b or 23a is smaller than the width Wₑ₁, at the corresponding end of openings 23a or 23b disposed nearer to an end of the opening member 23. Alternatively, when the vapor deposition material which passes through openings different from each other, respectively, is mixed with each other, the partitioning member 25 may be members disposed adjacent to side portions of the vapor depositing source 20 as illustrated in FIG. 9.

In the structure having the partitioning member described in the above, when the vapor depositing source and the opening member are moved, it is preferable that the partitioning member is also moved together with the vapor depositing source and the opening member. It is also possible to provide the partitioning member over the whole range of movement of the vapor depositing source, but the system has to become larger and the maintenance becomes complicated, and thus, the former is superior to the latter.

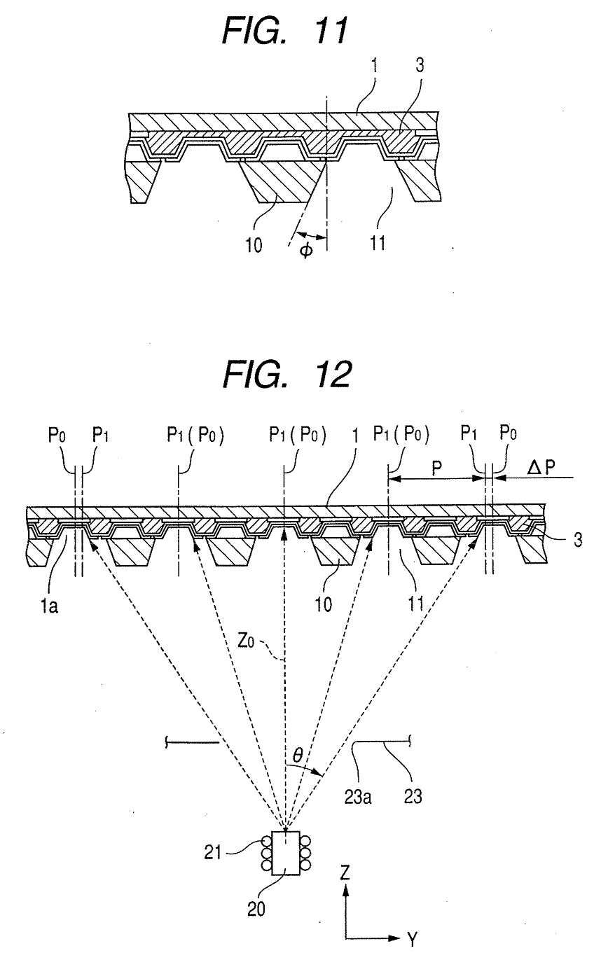

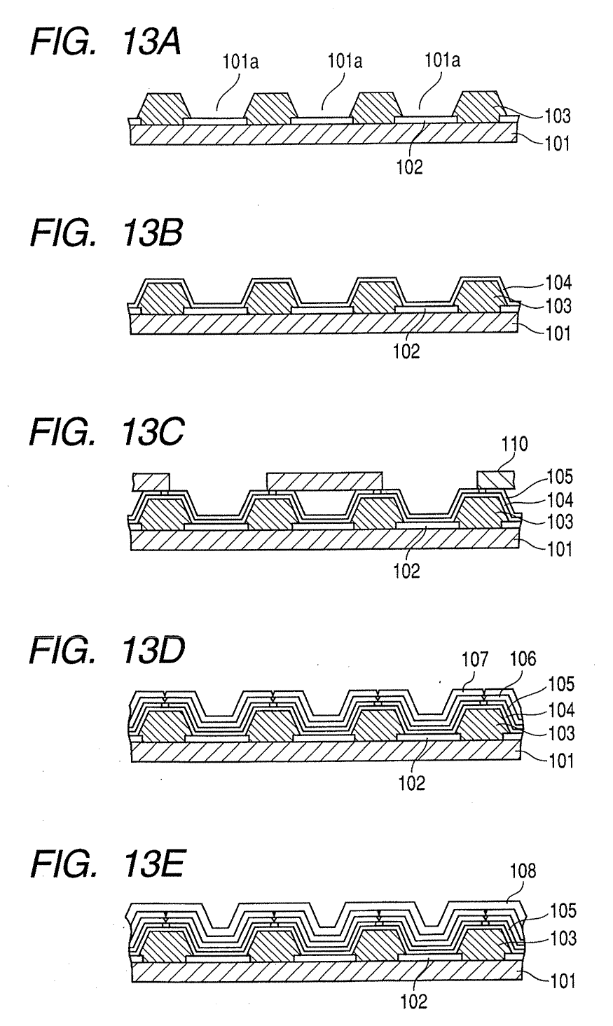

The shape of the openings in the mask may be anything which corresponds to a desired vapor deposition pattern. For example, when, in order to manufacture a full color organic EL display device, the mask 10 is used to apply the corresponding vapor deposition material to the corresponding pixels, the structure may be as illustrated in FIGS. 11 and 12.

With reference to FIG. 3, at a place H₁, of the opening 11 in the mask 10 corresponding to a place near the center of the film thickness correcting plate 23, the evaporated organic compound is substantially vertically incident on the substrate 1, and thus, the opening 11 in the mask 10 does not cast a shadow on the deposited film. However, the organic compound which passes through a place H₃ corresponding to a place near an end of the opening in the film thickness correcting plate 23 is obliquely incident on the substrate 1, and thus, it is necessary to prevent the opening 11 in the mask 10 from casting a shadow on a light-emitting region of a pixel. In order to attain this, as illustrated in FIG. 11, the mask 10 on the periphery of the opening 11 is tapered so as to form an angle of φ such that the area of the opening becomes smaller along the direction of incidence.

Alternatively, as illustrated in FIG. 12, the center P₁ of the opening 11 in the mask 10 corresponding to an end of the opening in the film thickness correcting plate 23 is shifted by ΔP with respect to the center P₀ of a pixel of the substrate 1 such that the shadow cast by the opening 11 in the mask 10 is formed outside the device. In other words, a region is provided in at least a part of the mask 10 in which the pitch P of the openings in the mask 10 is smaller by ΔP than the pitch of the pixels.

Alternatively, the structure may be such that the area of the openings is decreased from the side of the vapor depositing source toward the side of the substrate, and, at the same time, such that the centers of at least a part of the openings in the mask are slightly offset in the Y direction from the centers of the corresponding pixels. This can make more uniform the film thickness distribution of the organic compound deposited on the substrate, and thus, fluctuation of the brightness of the organic EL display device and variation in the viewing angle characteristics can be suppressed.

Examples and a reference example of the present invention and their comparative examples are now described in the following.

### REFERENCE EXAMPLE

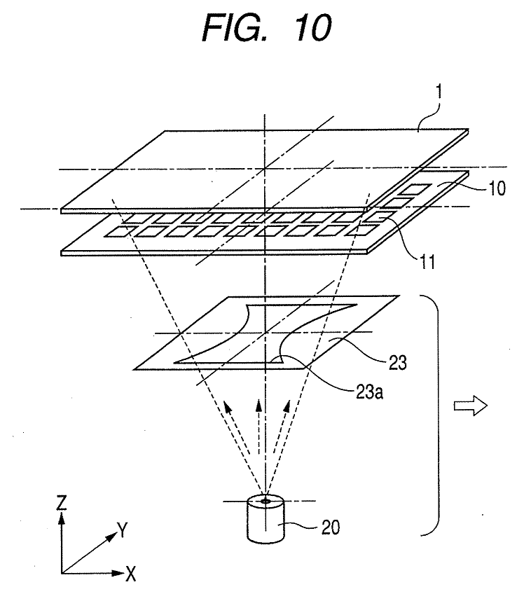

FIG. 10 is a perspective view illustrating the positional relationship among the vapor depositing source 20, the film thickness correcting plate 23, the mask 10, and the substrate 1 of a vapor deposition system according to a reference embodiment of the present invention. More specifically, the reference embodiment is an embodiment having one vapor depositing source and one film thickness correcting plate corresponding to the vapor depositing source.

An organic light emitting device was manufactured using the vapor deposition system illustrated in FIG. 10. The film thickness correcting plate 23 was disposed between the vapor depositing source 20 and the substrate 1. The vapor depositing source 20 and the film thickness correcting plate 23 were moved together with the substrate 1 in a fixed state. The width in the X direction of the opening 23a in the film thickness correcting plate 23 had a distribution along the Y direction, and was increased from the center of the opening toward the ends of the opening as illustrated in FIG. 10 and FIG. 3. The center of the opening 23a in the film thickness correcting plate 23 was aligned with the center of the vapor depositing source 20.

This system was used to manufacture an organic light emitting device on the substrate 1 of 400 mm×500 mm.

The substrate 1 was placed such that the length direction thereof is in parallel with the X direction. The distance between the vapor depositing source 20 and the substrate 1 was 350 mm. The shape of the opening in the film thickness correcting plate 23 was in the shape of an hourglass, and the dimensions were as follows: the length H in the Y direction was 410 mm; the width Wc of the opening in the X direction at a place corresponding to the center of the vapor depositing source 20 was 150 mm; and the largest width We of the opening in the X direction at the ends of the opening was 550 mm.

Next, the manufacturing process of the organic light emitting device is described. First, an anode electrode was formed on the substrate 1 provided with a TFT. Then, the device separating film 3 disposed between pixels was formed. After that, vacuum baking was carried out to remove moisture contained in the device separating film 3, and further, after the substrate 1 was once cooled, the substrate 1 was cleaned with UV/ozone. Then, a hole transporting layer, an organic light emitting layer (organic compound layer), an electron transporting layer, and an electron injecting layer were laminated in sequence by vapor deposition. It is to be noted that, in the vapor deposition of the organic compound to be the organic light emitting layer, a corresponding mask 10 adapted for the respective colors was used to form pixels differently from one another.

A transparent conductive film was formed on that as a cathode electrode. It is to be noted that, with regard to the vapor deposition rates of the respective organic compounds, the one for a host material was about 10 nm/sec as a reference value, and the ones for guest materials were determined according to their respective weight ratios. The velocity of the movement of the vapor depositing source 20 and the film thickness correcting plate 23 was 20 mm/sec.

The film thickness distribution of the organic compound layer on the substrate obtained according to the above-described process was ±5% or less. The process yield which is the ratio of the amount of deposition on the substrate 1 to the whole evaporated amount from the start to the end of the vapor deposition on the substrate 1 was about 12%.

### Comparative Example 1

A film thickness correcting plate having an opening shaped such that only components which were substantially vertically incident on the substrate pass therethrough was used to vapor deposit the organic compound in a method similar to that of the reference example. When only the vertical component are used for the vapor deposition as the incident component, in order to make uniform the film thickness distribution of the vapor deposition film, it is necessary to make larger the distance between the substrate and the vapor depositing source than that in the reference example. For example, when a film thickness distribution of ±5% or less was to be attained on a substrate of 400 mm×500 mm similarly to the case of the reference example, the distance between the substrate and the vapor depositing source was required to be 1000 mm or more, and the process yield here was less than 0.1%. The time period necessary for the vapor deposition was about 8.6 times as long as that of the reference example.

### Example 1

The system illustrated in FIG. 2 was used to manufacture an organic light emitting device. The substrate 1 of 400 mm×500 mm was used. The substrate 1 was placed such that the width direction thereof was in parallel with the X direction. The distance between the vapor depositing sources 20 and the substrate 1 was 280 mm. The structure was such that two vapor depositing sources 20 and the film thickness correcting plate 23 were fixed while the substrate 1 was moved. There were two openings 23a and 23b in the film thickness correcting plate 23 so as to correspond to the respective vapor depositing sources 20a and 20b.

Here, the shape of the openings in the film thickness correcting plate 23 was in the shape of an hourglass, and the dimensions were as follows: the length in the Y direction was 260 mm; the width of the openings in the X direction at places corresponding to the centers of the vapor depositing sources 20 was 160 mm; and the largest width of the openings in the X direction at the ends of the openings was 310 mm. Under the above conditions, the organic light emitting device was manufactured similarly to the case of the reference example. It is to be noted that, with regard to the vapor deposition rates of the respective organic compounds, the one for a host material was about 10 nm/sec as a reference value, and the ones for guest materials were determined according to their respective weight ratios. The velocity of the movement of the substrate 1 was 20 mm/sec.

The film thickness distribution of the organic compound layer on the substrate obtained according to the above-described process was ±5% or less. The process yield was about 12%. By using two vapor depositing sources, the vapor deposition process was completed with the takt time being about half as long as that of the reference example.

### Comparative Example 2

A film thickness correcting plate having an opening such that only components which were substantially vertically incident on the substrate pass therethrough was used to vapor deposit the organic compound in a method similar to that of Example 1. When two vapor depositing sources are used and only vertical components are used for the vapor deposition, in order to make uniform the film thickness distribution of the vapor deposition film, it is also necessary to make larger the distance between the substrate and the vapor depositing sources than that in the reference example. For example, when a film thickness distribution of ±5% or less was to be attained on a substrate of 400 mm×500 mm similarly to the case of the reference example, the distance between the substrate and the vapor depositing sources was required to be 450 mm or more, and the process yield here was less than 0.1%. The time period necessary for the vapor deposition was about 2.6 times as long as that of the reference example.

### Example 2

A substrate of 400 mm×500 mm was used. The substrate was placed such that the length direction thereof was in parallel with the X direction. As illustrated in FIG. 11, end faces of the respective openings 11 in the mask 10 were tapered so as to form an angle φ=about 15°, and with this, the distance between the vapor depositing source and the substrate could be made to be 250 mm.

The above-described system was used to manufacture an organic light emitting device similarly to the case of the reference example. It is to be noted that, with regard to the vapor deposition rates of the respective organic compounds, the one for a host material of about 12.5 nm/sec was a reference value, and the ones for guest materials were determined according to their respective weight ratios. The velocity of the movement of the vapor depositing source was 20 mm/sec.

The film thickness distribution of the organic compound layer on the substrate obtained according to the above-described process was ±5% or less. The process yield was about 12%. By making the vapor deposition rate 1.25 times as much as that of the reference example, the vapor deposition process was completed with the takt time being about ⅘ of that of the reference example.

### Example 3

Similarly to the case of Example 2, a substrate of 400 mm×500 mm was used. The substrate was placed such that the length direction thereof was in parallel with the X direction. The distance between the vapor depositing source and the substrate was 250 mm.

As illustrated in FIG. 12, end faces of the respective openings 11 in the mask 10 were tapered so as to form an angle of about 15°, and the pitch P of the openings in the mask 10 was adjusted so as to be, at the ends of the openings in the film thickness correcting plate 23, shifted by ΔP =10 μm from the centers P₀ of pixels on the substrate 1. It is to be noted that there was no shift with regard to the center of the openings in the film thickness correcting plate 23. With this, the width of the openings in the film thickness correcting plate 23 could be made larger. The width Wc of the openings at the center was 170 mm. The rest of the dimensions were determined according to the equations (2).

The above-described system was used to manufacture an organic light emitting device similarly to the case of the reference example. It is to be noted that, with regard to the vapor deposition rates of the respective organic compounds, the one for a host material of about 12.5 nm/sec was a reference value, and the ones for guest materials were determined according to their respective weight ratios. The velocity of the movement of the vapor depositing source 20 and the film thickness correcting plate 23 was 20 mm/sec.

The film thickness distribution of the organic compound layer on the substrate obtained according to the above-described process was ±5% or less. The process yield was about 14%. By making the vapor deposition rate 1.25 times as much as that of the reference example, the vapor deposition process was completed with the takt time being about ⅘ of that of the reference example.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-018519, filed Jan. 27, 2006, and Japanese Patent Application No. 2007-001935, filed Jan. 10, 2007, which are hereby incorporated by reference herein in their entirety.

What is claimed is:

1. A vapor deposition system comprising:
(A) a plurality of vapor depositing sources;
(B) a holding member for holding a substrate on which a film is to be formed;
(C) an opening member disposed between the vapor depositing source and the substrate on which a film is to be formed, the opening member having openings each independently disposed so as to correspond to the plurality of vapor depositing sources; and
(D) moving means for moving at least one of the substrate on which a film is to be formed, and, the vapor depositing sources and the opening member, in one direction in a plane in parallel with a plane including the held substrate on which a film is to be formed, wherein
the plurality of vapor depositing sources are arranged along a direction in the plane, which is the direction intersecting the direction of the movement, and
a width at a center of the opening in the direction of movement is smaller than that at ends of the opening.

2. The vapor deposition system according to claim 1, further comprising a partitioning member disposed between the plurality of vapor depositing sources.

3. The vapor deposition system according to claim 2, wherein the partitioning member is disposed both a space between the vapor depositing sources and the opening member and a space bewteen the openign member and the substrate on which a film is to be formed.

4. The vapor deposition system according to claim 1, wherein the width of the opening in the one direction at one end nearer to an adjacent opening is smaller than that at the other end.

5. The vapor deposition system according to claim 1, wherein the moving means is means for moving the substrate on which a film is to be formed.

6. The vapor deposition system according to claim 1, wherein a distribution of evaporation rate of a vapor deposition material evaporated from the vapor depositing source is in a shape of concentric circle or concentric oval with respect to the center of the vapor depositing source.

7. A vapor deposition system comprising:
(A) a plurality of vapor depositing sources;
(B) a holding member for holding a substrate on which a film is to be formed;
(C) a plurality of opening members each disposed between the vapor depositing sources and the substrate on which a film is to be formed, the plurality of opening members being independently disposed so as to correspond to the plurality of vapor depositing sources;
(D) moving means for moving at least one of the substrate on which a film is to be formed, and, the vapor depositing sources and the opening members, in one direction in a plane in parallel with a plane including the held substrate on which a film is to be formed; and
(E) a partitioning member disposed between the plurality of vapor depositing sources, wherein
the plurality of vapor depositing sources are arranged along a direction in the plane, which is a direction intersecting the direction of the movement, and
a width at a center of each of the openings in the direction of movement of the openings is smaller than that at ends of the each of the openings.

8. A method of manufacturing an organic light emitting device comprising a vapor deposition step of an organic compound,
the vapor deposition step of an organic compound comprising the steps of:
moving at least one of a substrate on which a film is to be formed, and, a plurality of vapor depositing sources and an opening member, in one direction in a plane in parallel with a plane including the substrate on which a film is to be formed;
evaporating the organic compound from the vapor depositing sources; and
making the evaporated organic compound pass through the opening member to form a film on the substrate on which a film is to be formed, wherein:
the opening member has a plurality of openings provided therein;
a width at a center of each of the openings in the one direction of the each of the openings is smaller than that at ends of the each of the openings, and
the plurality of openings are each independently provided so as to correspond to the respective plurality of vapor depositing sources.

9. A vapor deposition method for an organic compound for forming an organic compound layer on a plurality of pixels arranged on a substrate having an electrode through a mask having a plurality of openings provided therein corresponding to the arranged pixels,
the method comprising a vapor deposition step of depositing the organic compound evaporated from a vapor depositing source through the mask on the substrate while relatively moving the vapor depositing source in a first direction with respect to the substrate and the mask,
wherein an area of the openings in the mask is decreased from a side of the vapor depositing source toward the substrate in a thickness direction of the mask.

10. A vapor deposition method for an organic compound for forming an organic compound layer on a plurality of pixels arranged on a substrate having an electrode through a mask having a plurality of openings provided therein corresponding to the arrangement of the pixels,
the method comprising a vapor deposition step of the organic compound evaporated from a vapor depositing source through the mask on the substrate while relatively moving the vapor depositing source in a first direction with respect to the substrate and the mask,
wherein, in a part of the mask, a center of each of the openings in the mask and a center of each of the pixels are offset with each other in a second direction orthogonal to the first direction.
